(19) United States
(12) Patent Application Publication
(10) Pub. No.: US 2014/0028088 A1
(43) Pub. Date: Jan. 30, 2014

(54) Method for Controlling a Battery System, a Battery System, and Motor Vehicle

(71) Applicants: Samsung SDI Co., Ltd., Yongin-si (KR); Robert Bosch GmbH, Stuttgart (DE)

(72) Inventors: Jan Salziger, Esslingen (DE); Joshua Anzicek, Clarkston, MI (US); Joachim Rischen, Lake Orion, MI (US)

(73) Assignees: Samsung SDI Co., Ltd., Yongin-si (KR); Robert Bosch GmbH, Stuttgart (DE)

(21) Appl. No.: 13/949,344

(22) Filed: Jul. 24, 2013

(30) Foreign Application Priority Data
Jul. 25, 2012 (DE) 10 2012 213 057.8

(51) Int. Cl. H02J 7/00; G01R 27/26; B60R 16/02

(52) U.S. Cl. CPC H02J 7/00; B60R 16/02; G01R 27/2605
USPC 307/9.1; 320/166; 324/679; 702/65

(57) ABSTRACT

A battery system comprises at least one battery cell and a high-voltage network connected thereto which includes a pre-charge circuit having at least one pre-charge resistor. The battery system further comprises a component including a link capacitor with a specific capacitance. A method for controlling the battery system includes measuring a first voltage at the link capacitor before charging, charging the link capacitor, and measuring a second voltage at the link capacitor after charging. The method further includes forming a voltage difference from the first and the second voltage, and determining an energy received by the pre-charge resistor based on the voltage difference at the link capacitor and based on the capacitance of the link capacitor.

This application claims priority under 35 U.S.C. § 119 to patent application no. DE 10 2012 213 057.8, filed on Jul. 25, 2012 in Germany, the disclosure of which is incorporated herein by reference in its entirety.

### BACKGROUND

The present disclosure relates to a method for controlling a battery system, a battery system having a battery management unit that is designed to carry out the method, and a motor vehicle having the battery system.

In hybrid and electric vehicles, battery packs are connected by power contactors to the further vehicle components, such as the drive, booster generator, charging plug, etc. Often, this component is fed via a device that generates a single-phase or multi-phase a.c. voltage or pulsed d.c. voltage from the battery voltage. Due to the peak loads that occur here, such devices are provided with an electrical storage device, normally a capacitor. Such capacitors generally have a high capacitance and are also referred to as link capacitors.

If a vehicle component is to be connected, a link capacitor is first charged and the vehicle component itself is then put into operation. Such a link capacitor is normally charged using a pre-charge circuit. Here, quick charging generates high currents in feed lines, structural elements of the pre-charge circuit, and the link capacitor. These currents can reduce the service life of these structural elements. Slow charging is gentle on the structural elements, but requires correspondingly more time before the vehicle components can be put into operation.

DE 10 2010 038 892 A1 also describes a monitoring unit that captures operating data of a pre-charge circuit in order to estimate the current temperature of a pre-charge resistor. The monitoring unit does not use a temperature sensor arranged on the pre-charge resistor for this purpose, but measures the current flowing through the pre-charge resistor, a battery voltage, the number of starting operations per unit of time, the duration of the starting operations and the ambient temperature, and estimates from this the current temperature. If the current temperature lies above a threshold value, the pre-charge resistor may thus be overheated and cannot be operated further.

### SUMMARY

In accordance with the disclosure, a method for controlling a battery system is provided. The battery system comprises at least one battery cell and a high-voltage network connected thereto which comprises a pre-charge circuit having at least one pre-charge resistor. The battery system further comprises a component having a link capacitor with a specific capacitance. The method comprises at least the following steps: measuring a first voltage at the link capacitor before charging, charging the link capacitor, measuring a second voltage at the link capacitor after charging, forming a voltage difference from the first and second voltage, and determining an energy received by the pre-charge resistor based on the voltage difference at the link capacitor and based on the capacitance of the link capacitor.

A battery system having a battery management unit that is designed to carry out the method is also proposed.

In addition, a motor vehicle having the battery system is proposed, the battery system being connected to a drive system of the motor vehicle.

The method according to the disclosure makes it possible to determine the energy actually received by the pre-charge resistor. In order to limit a maximum thermal loading of the pre-charge resistor, known methods usually count the number of link capacitor charging operations carried out. If a specific number is exceeded, charging via the pre-charge resistor was previously prevented. This conventional counting method does not take into consideration however the fact that the link capacitor can also be charged a number of times in succession by just a low voltage, such that the heat energy output by the pre-charge resistor over a considered period of time is lower than with practically complete charging of the link capacitor.

Furthermore, the method according to the disclosure makes it possible to determine a thermal loading of the pre-charge resistor and to thus attain a better availability of a battery system. The service life of the components involved in the pre-charging operation can be increased. The reliability of battery systems can also be improved by means of the method according to the disclosure.

In a further embodiment of the method, an energy received by the pre-charge resistor in a worst-case scenario can be determined. The worst-case scenario in particular comprises a situation in which the pre-charge resistor is exposed for a specific time to a high current. That is possible in the event of a fault, wherein the connected component is short-circuited and the full voltage at the pre-charge resistor drops until the battery management unit interrupts the pre-charging operation. If the full battery voltage is applied to the pre-charge resistor, the received energy can be determined by forming a quotient from battery voltage squared divided by the ohmic resistance of the pre-charge resistor, wherein the quotient is multiplied by the duration of the high current flow. The pre-charge resistor is preferably designed such that it withstands such individual current pulse loads.

In a further preferred method step, the energy output by the pre-charge resistor can be determined. In order to determine whether the pre-charge resistor has received or is about to receive a critical energy, the balance of received energy and output energy is to be determined in particular. Here, the output energy is substantially dependent on the heat capacity of the pre-charge resistor, the temperature thereof, and the temperature difference from the ambient environment. It is also preferable for the pre-charge resistor to determine a maximum power over a specific period of time. This maximum power can be based on a thermal loadability of the pre-charge resistor and on the energy output by the pre-charge resistor. If the maximum power is exceeded over a specific period of time, the pre-charge resistor may be overloaded.

It is preferable for the method to further comprise the following step: predicting the charging curve of the link capacitor. The charging curve of capacitors generally follows a l-e^{x} function, wherein x is the quotient with the time in the counter and the pre-charge resistor multiplied by the capacitor capacitance in the denominator. The l-e^{x} charging curve approximates the charging voltage applied to the pre-charge circuit, that is to say in particular the battery voltage, during the charging of the link capacitor. It is also preferable to measure the charging curve of the link capacitor and to compare the predicted charging curve with the measured charging curve. In the event of a deviation between the predicted charging curve and the measured charging curve, a fault can be determined. The fault may be present in the battery system or in one of its components, for example the link capacitor.

In a further preferred embodiment, the method may further comprise the following step: discharging the link capacitor via a discharge circuit that comprises a discharge relay and a discharge resistor.

In a further embodiment, the battery system may comprise at least one battery cell, a high-voltage network and a component. The high-voltage network is connected in particular to the at least one battery cell and basically comprises a pre-charge circuit. The pre-charge circuit may comprise an operational contactor and a series circuit formed from a pre-charge contactor and a pre-charge resistor, wherein the series circuit is connected in parallel to the operational contactor. The component preferably comprises a link capacitor, wherein the pre-charge circuit and the component can form a series circuit with the at least one battery cell. The component further comprises a discharge circuit, which preferably comprises a discharge relay and a discharge resistor connected in series to the discharge relay. The discharge circuit is in particular connected in parallel to the link capacitor.

The battery system is preferably a lithium-ion battery system.

### BRIEF DESCRIPTION OF THE DRAWINGS

Exemplary embodiments of the disclosure will be explained in greater detail with reference to the drawings and the following description. In the drawings:

FIG. 1 shows a battery system in accordance with an exemplary embodiment of the disclosure,

FIG. 2 shows a graph that illustrates a power consumption of a link capacitor,

FIG. 3 shows a further graph that illustrates a power consumption of a link capacitor,

FIG. 4 shows a method in accordance with an exemplary embodiment of the disclosure, and

FIG. 5 shows a method in accordance with a further exemplary embodiment of the disclosure.

### DETAILED DESCRIPTION

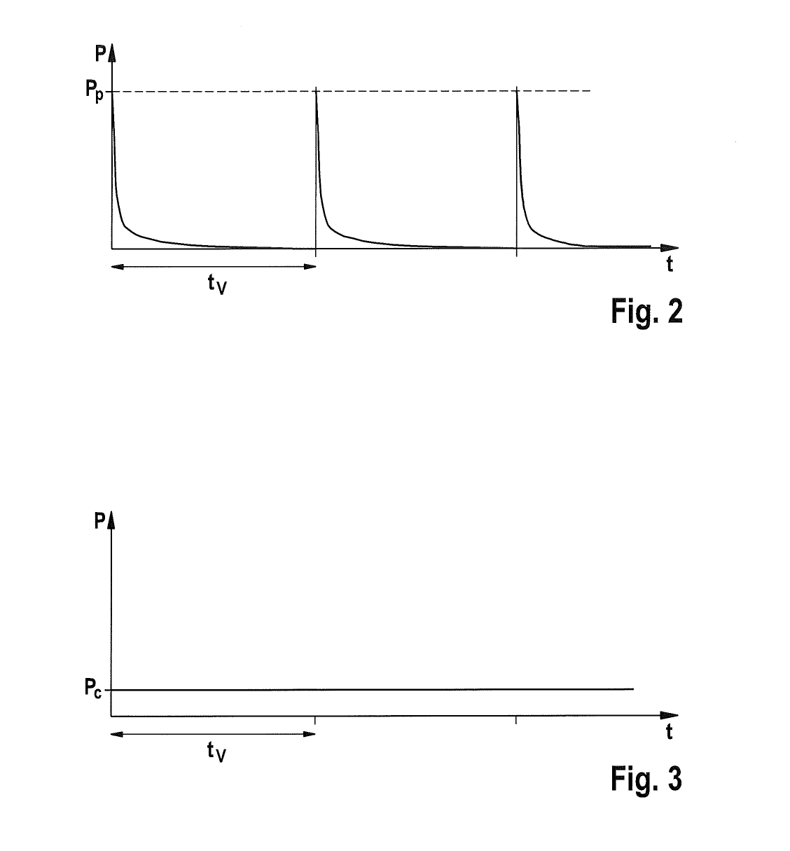

Within the scope of this patent application, the terms “received energy” and “output energy” are used. Received energy is electrical energy as a result of a flow of current. An example of the received energy will be discussed within the scope of FIG. 2. The output energy is thermal or heat energy.

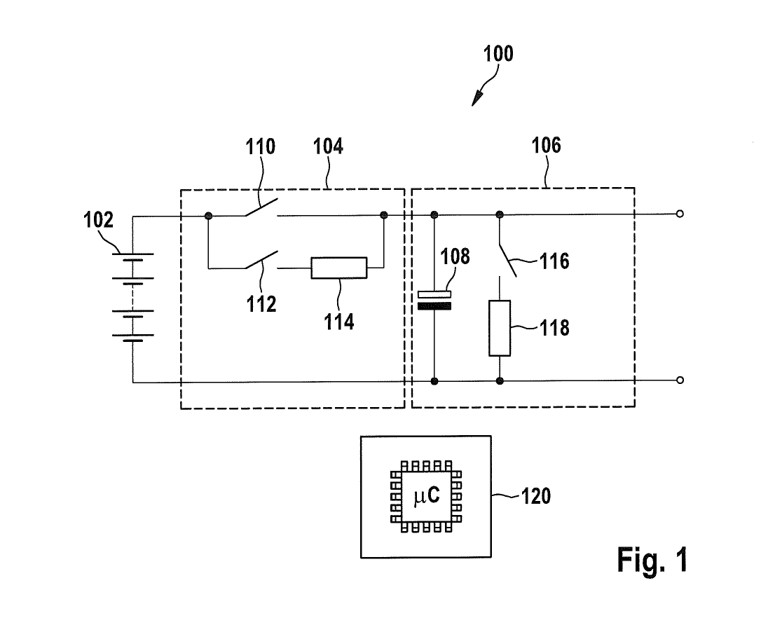

FIG. 1 shows a battery system 100 in accordance with an exemplary embodiment of the disclosure that illustrates a series connection of a plurality of lithium-ion battery cells 102 and a high-voltage network 104, wherein the high-voltage network 104 is connected to the series connection of the plurality of lithium-ion battery cells 102. The high-voltage network 104 can be connected to a further component 106, for example a link capacitor 108, a discharge circuit, pulse-width-modulation inverter, or other consumers, such as electric motors, etc.

The high-voltage network 104 comprises a pre-charge circuit that in turn comprises an operational contactor 110 and a series circuit formed from a pre-charge contactor 112 and a pre-charge resistor 114, wherein this series circuit is connected in parallel to the operational contactor 110. The pre-charge circuit and the link capacitor 108 form a series circuit with the lithium-ion battery cells 102. The lithium-ion battery cells 102 form a battery or an accumulator.

The discharge circuit comprises an end relay 116 and a discharge resistor 118 connected in series to the discharge relay 116. The discharge circuit is connected in parallel to the component 106 or to the link capacitor 108.

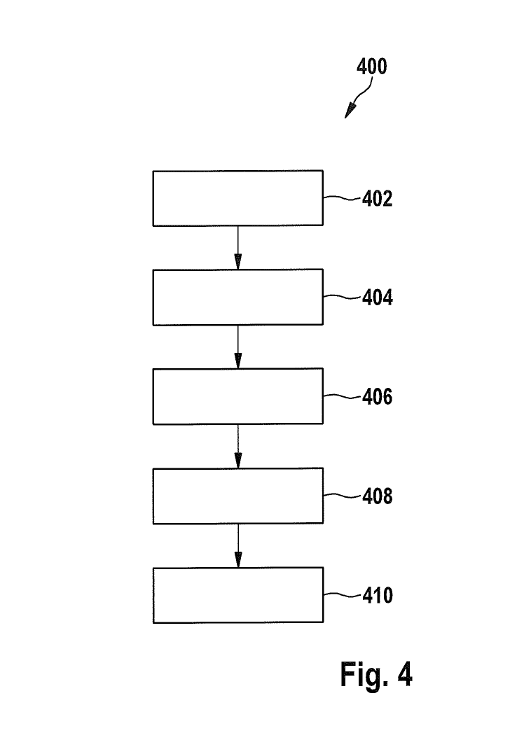

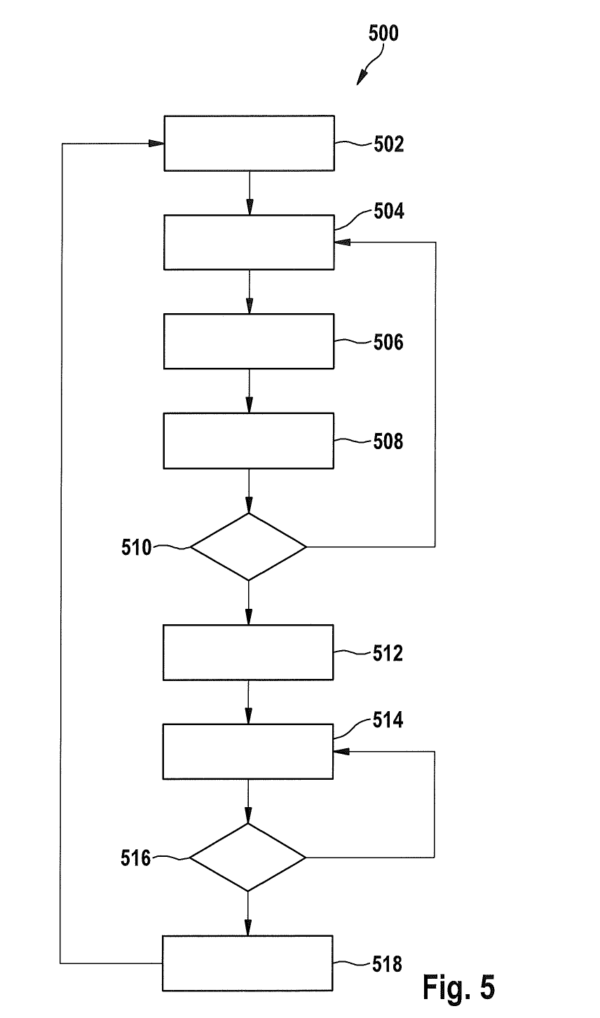

The battery system 100 further comprises a battery management unit 120, which is designed to carry out one of the methods described hereinafter with reference inter alia to FIGS. 4 and 5.

The operation of vehicle components, such as electric motors, booster generators, and charging units as consumers at the battery system 100 causes peak loads, in particular when said vehicle components are switched on or off, said peak loads normally being buffered by an electronic storage device in the battery system 100. The link capacitor 108 forms such an electronic storage device. If a vehicle component is connected to the battery system 100, the link capacitor 108 is thus initially charged, then the vehicle component itself can be put into operation. The link capacitor 108 is charged from the lithium-ion battery cells 102 via the pre-charge resistor 114, wherein the battery management unit 120 controls the pre-charge contactor 112 in such a way that it connects the pre-charge resistor 114 to the lithium-ion battery cells 102. Once charging of the link capacitor 108 is complete, the battery management unit 120 closes the operational contactor 110 in order to put the vehicle component into operation.

Quick charging of the link capacitor 108 generates high currents in feed lines and in structural elements of the high-voltage network 104. The high currents reduce the service life of the feed lines and structural elements concerned. Slow charging would indeed be gentle on the structural elements, but requires correspondingly more time before the vehicle component can be put into operation.

The current through the link capacitor 108 decreases to the extent that it is charged. In this regard, FIG. 2 shows the curve of the power received by the pre-charge resistor 114 during charging over the period tₗ. The area below the power curve shown in FIG. 2 corresponds to the energy received by the pre-charge resistor. Here, with the onset of charging of the capacitor, a high power Pₚ is received in the resistor and is converted into heat. FIG. 2 shows three successive pre-charging operations, for example.

Here, the loading of a plurality of charging operations carried out corresponds to the individual loads added over the period of time tᵥ, as is shown in FIG. 3 by the power curve P_{c}.

A method 400 in accordance with an exemplary embodiment of the disclosure is shown in FIG. 4. In a first step 402, the battery management unit 120 measures a first voltage at the link capacitor 108. In a subsequent step 404, the battery management unit 120 controls the pre-charge circuit in such a way that the link capacitor 108 is charged. In a subsequent step 406, the battery management unit 120 measures a second voltage at the link capacitor 108 after the charging operation and then forms, in step 408, a voltage difference from the first and the second measured voltage. The battery management unit 120, in a subsequent step 410, determines an energy received by the pre-charge resistor.

A method 500 in accordance with a further exemplary embodiment of the disclosure is shown in FIG. 5. In a first method step 502, a start temperature of the pre-charge resistor is extracted from a non-volatile memory, or for example is determined at an ambient temperature of approximately 60° C. In a subsequent step 504, an energy output from the pre-charge resistor in the form of heat is determined, wherein the heat output causes a cooling of the pre-charge resistor.

The heat output and therefore a temperature change of the pre-charge resistor can be determined in step 504 as follows:

$$T = T - ( W \cdot \frac{1}{{C}_{p}} ) = T - ( {G}_{th} \cdot ( T - {T}_{ambient , max} ) \cdot {t}_{elapsed} ) \cdot \frac{1}{{C}_{p}}$$

In this case, T is the determined current temperature of the pre-charge resistor; W is the energy output by the pre-charge resistor; Cₚ is the heat capacity of the pre-charge resistor in the unit of joules per kelvin; Gₜₕ is the thermal conductance in the unit of watts per kelvin at ambient temperature; T_{ambient,max} is the maximum ambient temperature and t_{elapsed} is the time elapsed during the heat output.

In a subsequent step 506, an energy received by the pre-charge resistor in the worst-case scenario is determined as follows:

$${W}_{w . c .} = \frac{{U}^{2} battery}{{R}_{v}} \cdot t$$

In this case, W_{w.c.} is the energy received by the pre-charge resistor 114 in the worst-case scenario in the unit of joules, given from the total voltage of the battery cells 102, that is to say the battery voltage U_{battery}, the ohmic resistance Rᵥ of the pre-charge resistor, and the time t during which energy is received.

In a subsequent step 508, the temperature T_{w.c.} of the pre-charge resistor 114 in the worst-case scenario is determined as follows:

$${T}_{w . c .} = T + {W}_{w . c .} \cdot \frac{1}{{C}_{p}}$$

In this case, T is the current temperature of the pre-charge resistor 114, that is to say for example the ambient temperature in a first method run-through.

In a subsequent step 510, the condition as to whether the temperature in the worst-case scenario T_{w.c.} is less than a fixed maximum temperature for the pre-charge resistor is checked. If the condition is met, the method branches to a subsequent step 512, in which the link capacitor 108 is charged or pre-charged. If the condition in step 510 is not met, the method 500 branches back to step 504, in which the pre-charge resistor 114 is cooled or the cooling of the pre-charge resistor 114 is determined.

In step 514, the energy actually received by the pre-charge resistor is determined as follows:

$$W = W + \frac{{( {U}_{battery} - {U}_{link} )}^{2}}{{R}_{v}} \cdot {t}_{charge}$$

In this case, W is the determined energy that is received by the pre-charge resistor; U_{battery} is the total voltage of the battery; wherein the voltage of connection elements Uₗᵢₙₖ between the battery cells and the pre-charge resistor 114 is subtracted from said total voltage; Rᵥ is the ohmic resistance of the pre-charge resistor; and t_{charge} is the time elapsed during the charging of the link capacitor 108.

In a subsequent step 516, the condition as to whether the pre-charging operation is complete is checked. If the condition is met, the method 500 branches to the next step 518. If the condition in step 516 is not met, the method 500 branches back to step 514 and the link capacitor 108 is charged further, during which time the energy received by the pre-charge resistor continues to be determined.

In step 518, the heating or the temperature T of the pre-charge resistor 114 present once the pre-charging of the link capacitor 108 has ended is determined as follows:

$$T = T + W \cdot \frac{1}{{C}_{p}}$$

The methods described with reference to FIGS. 4 and 5 can be used for thermal protection of the pre-charge resistor 114 in the battery system 100, wherein the battery management unit 120 is designed to carry out such a method. The battery system 120 can in turn be used in a motor vehicle and can provide a greater reliability of the motor vehicle.

In accordance with Ohm's law, instead of determining the voltage before and after the pre-charging operation, the flow of current during the pre-charging operation can also be measured. The formulas for the received energy of the pre-charge resistor apply accordingly in this regard.

In a further exemplary embodiment, a further pre-charge circuit can be used instead of the pre-charge resistor in order to charge the link.

What is claimed is:

1. A method for controlling a battery system including at least one battery cell and a high-voltage network connected to the at least one battery cell, the high-voltage network including a pre-charge circuit having at least one pre-charge resistor, and a component having a link capacitor with a specific capacitance, the method comprising:
measuring a first voltage at the link capacitor before charging the link capacitor;
charging the link capacitor;
measuring a second voltage at the link capacitor after charging the link capacitor;
forming a voltage difference from the first voltage and second voltage; and
determining an energy received by the pre-charge resistor based on the voltage difference at the link capacitor and further based on the specific capacitance of the link capacitor.

2. The method according to claim 1, further comprising:
determining an energy W_{w.c.} received by the pre-charge resistor in a worst-case scenario in accordance with:
$${W}_{w . c .} = \frac{{U}^{2} battery}{{R}_{V}} \cdot t ,$$
wherein U_{battery} is the battery voltage,
wherein Rᵥ is the ohmic resistance of the pre-charge resistor, and
wherein t is the time during which energy is received.

3. The method according to claim 1, further comprising:
determining a heat energy output by the pre-charge resistor.

4. The method according to claim 3, further comprising:
determining a maximum power over a specific period of time for the pre-charge resistor based on (i) a thermal loadability of the pre-charge resistor, and (ii) the heat energy output by the pre-charge resistor.

5. The method according to claim 1, further comprising:
predicting a charging curve of the link capacitor.

6. The method according to claim 5, further comprising:
measuring the charging curve of the link capacitor; and
comparing the predicted charging curve with the measured charging curve.

7. The method according to claim 6, further comprising:
determining a fault in the event of a deviation between the predicted charging curve and the measured charging curve.

8. The method according to claim 1, further comprising:
discharging the link capacitor via a discharge circuit which includes a discharge relay and a discharge resistor.

9. A battery system comprising:
a battery management unit configured to carry out a method for controlling the battery system,
wherein the method includes
measuring a first voltage at a link capacitor before charging the link capacitor,
charging the link capacitor,
measuring a second voltage at the link capacitor after charging the link capacitor,
forming a voltage difference from the first voltage and second voltage, and
determining an energy received by a pre-charge resistor based on the voltage difference at the link capacitor and further based on a capacitance of the link capacitor.

10. The battery system according to claim 9, further comprising:
at least one battery cell;
a high-voltage network connected to the at least one battery cell, the high-voltage network including a pre-charge circuit with an operational contactor, a first series circuit formed from a pre-charge contactor, and the pre-charge resistor, the first series circuit being connected in parallel to the operational contactor;
a component including the link capacitor, the pre-charge circuit and the component forming a second series circuit with the at least one battery cell; and
a discharge circuit including a discharge relay and a discharge resistor connected in series to the discharge relay, the discharge circuit being connected in parallel to the link capacitor.

11. A motor vehicle comprising:
a drive system; and
a battery system connected to the drive system, the battery system including (i) at least one battery cell, (ii) a high-voltage network connected to the at least one battery cell, the high-voltage network including a pre-charge circuit with an operational contactor, a first series circuit formed from a pre-charge contactor, and a pre-charge resistor, the first series circuit being connected in parallel to the operational contactor, (iii) a component including a link capacitor, the pre-charge circuit and the component forming a second series circuit with the at least one battery cell, and (iv) a discharge circuit including a discharge relay and a discharge resistor connected in series to the discharge relay, the discharge circuit being connected in parallel to the link capacitor; and
a battery management unit configured to carry out a method for controlling the battery system, the method including (i) measuring a first voltage at the link capacitor before charging the link capacitor, (ii) charging the link capacitor, (iii) measuring a second voltage at the link capacitor after charging the link capacitor, (iv) forming a voltage difference from the first voltage and second voltage, and (v) determining an energy received by the pre-charge resistor based on the voltage difference at the link capacitor and further based on a capacitance of the link capacitor.
